(19) United States
(12) Patent Application Publication
(10) Pub. No.: US 2020/0045833 A1
(43) Pub. Date: Feb. 6, 2020

(54) PRINTED WIRING BOARD AND METHOD FOR MANUFACTURING SAME

(71) Applicant: KANEKA CORPORATION, Osaka-shi (JP)

(72) Inventors: Yuji ASAHINA, Otsu-shi (JP); Tetsuya KOGISO, Otsu-shi (JP); Tomohiro KODA, Otsu-shi (JP); Masayoshi KIDO, Otsu-shi (JP)

(73) Assignee: KANEKA CORPORATION, Osaka-shi (JP)

(21) Appl. No.: 16/090,687

(22) PCT Filed: Apr. 17, 2017
(86) PCT No.: PCT/JP2017/015467

§ 371 Date: Oct. 2, 2018

(30) Foreign Application Priority Data
Apr. 19, 2016 (JP) 2016-083493

(51) Int. Cl. H05K 3/28; B41M 1/12; B41F 15/34; H05K 1/02; C08F 290/14

(52) U.S. Cl. CPC H05K 3/287; B41M 1/12; B41F 15/34; H05K 2201/0191; H05K 1/0296; H05K 1/0271; C08F 290/147; H05K 1/028

(57) ABSTRACT

A printed wiring board has conductor patterns (12) having a thickness (t1) of 50 μm or more on an insulating substrate (11). An insulating layer (5) is provided in regions (L) on the conductor patterns and on the insulating substrate in regions (S) between the conductor patterns. A thickness (t_{L}) of the insulating layer on the conductor patterns is preferably 0.1-1 times the conductor thickness (t₁). The insulating layer is formed on the conductor patterns and on the insulating substrate between the conductor patterns by printing a resin composition using screen printing and then curing the resin composition. The resin composition has a viscosity of 50-300 P at 25° C. and a thixotropic index of 1.1-3.5. A screen printing plate used for screen printing has a mesh thickness of 2.2 or more times a yarn diameter of yarns.

### TECHNICAL FIELD

The present invention relates to a printed wiring board having an insulating layer on conductor patterns and relates to a method for manufacturing the printed wiring board.

### TECHNICAL BACKGROUND

On a surface of a printed wiring board, a solder resist as an insulating layer is provided in order to cover and protect the wiring board and to maintain insulation between wirings. As the solder resist, a cover lay film, a cover coat ink, or the like is used.

In recent years, a wireless power supply system using electromagnetic induction has come into practical use. In the wireless power supply system, in order to increase power transmission and reception efficiency, for example, a printed wiring board having conductor patterns having a thickness of 50 μm or more is used (for example, see Patent Document 1). Even in such a wiring board (hereinafter referred to as “a thick conductor wiring board) having thick conductor patterns (hereinafter referred to as “thick conductor wirings”), it is necessary to cover a surface of the wiring board with an insulating protective layer.

When a cover coat ink used in a general flexible printed wiring board (conductor thickness: about 10-40 μm) is printed on a thick conductor wiring board, a portion where a film thickness of an insulating layer is extremely small or a portion where conductors are exposed without being covered by an insulating layer may occur, and, in particular, conductors are likely to be exposed at edge portions of wirings. Therefore, a cover lay film is often used as an insulating protective layer of a thick conductor wiring board. On the other hand, when a cover lay film is used as an insulating protective layer of a thick conductor wiring board, there may be a problem that voids may remain between the wirings and the cover lay film at stepped portions near side surfaces of the wirings (for example, see Patent Document 2).

The exposure of the conductors and the voids between the conductors and the insulating layer not only deteriorate the quality of the printed wiring board but also cause heat generation and electrical shorts of the wiring board. Patent Document 2 discloses that, by screen-printing an insulating resin layer on a thick conductor wiring board and then laminating thereon an adhesive sheet formed of the same insulating resin material, the problem of the exposure of the conductors and the problem of the voids between the conductors and the insulating layer can be solved.

### RELATED ART

### Patent Documents

Patent Literature 1: Japanese Patent Laid-Open Publication No. 2015-146358.
Patent Document 2: Japanese Patent Laid-Open Publication No. 2007-288022.

### SUMMARY OF THE INVENTION

### Problems to be Solved by the Invention

In the method of Patent Document 2, it is necessary to maintain the insulating resin layer coated on the wiring board in a semi-cured state and integrate thereon the adhesive sheet by laminating and heating the adhesive sheet. Therefore, the process is complicated and a material cost is also high.

In view of such a situation, the present invention is intended to provide a thick conductor wiring board in which, by applying a resin composition on a printed wiring board having thick conductor wirings, an insulating layer is satisfactorily covered on the thick conductor wirings and the insulating layer is satisfactorily embedded in gaps between the thick conductor wirings.

### Means for Solving the Problems

As a result of intensive studies to solve the above-described problem, the present inventors have found that, by screen-printing a resin composition having predetermined solution characteristics using a predetermined screen printing plate, a thick conductor wiring board can be satisfactorily covered by an insulating layer and the insulating layer can be satisfactorily embedded in gaps between conductor patterns.

The present invention relates to a printed wiring board in which conductor patterns having a thickness of 50 μm or more are provided on an insulating substrate and an insulating layer is provided on the conductor patterns and on the insulating substrate between the conductor patterns, and relates to a method for manufacturing the printed wiring board. A printed wiring board of an embodiment is a flexible printed wiring board in which a flexible resin substrate is used as an insulating substrate. The insulating substrate may have a flexible portion and a rigid portion. In order to maintain the flexibility of the wiring board, conductors provided on the flexible substrate preferably have a thickness of 100 μm or less.

In order to ensure satisfactory insulation, a thickness of an insulating layer between conductor patterns is preferably 0.5-2 times a conductor thickness. A thickness of an insulating layer on the conductor patterns at both centers and edges of the conductor patterns is preferably 0.1-1 times and more preferably 0.3-0.7 times the conductor thickness. A thickness of the insulating layer on the edges of the conductor patterns is preferably 0.3 or more times a thickness of the insulating layer on the centers of the conductor patterns.

The insulating layer is formed on the conductor patterns and on the insulating substrate between the conductor patterns by printing a resin composition using screen printing and then curing the resin composition. The resin composition for forming the insulating layer preferably has a viscosity of 50-300 P at 25° C. and a thixotropic index of 1.1-3.5.

A screen printing plate used for screen printing preferably has a mesh thickness of 2.2 or more times a yarn diameter of yarns. A specific example of a screen printing plate having a mesh thickness of 2.2 or more times a yarn diameter of yarns is a mesh fabric or the like of a structure in which warp yarns are woven into substantially straight weft yarns. The mesh thickness of the screen printing plate is preferably 40-200 μm, and is preferably 4.4 or less times the yarn diameter of the yarns. A hardness of a squeegee used for screen printing is preferably 55-85°, and an attack angle is preferably 60-90°.

The resin composition contains, for example, a binder polymer, a solvent, and a filler. As the filler, a spherical organic filler is preferable. As the binder polymer, for example, a urethane-based polymer is used. The resin composition may contain an epoxy resin. The resin composition may contain a compound having a carboxy group and a polymerizable group in a molecule. The resin composition may contain a photopolymerization initiator. A solid content concentration of the resin composition is preferably about 40-70 wt %.

### Effect of Invention

In the method of the present invention, by applying only the resin composition, the thick conductor wirings can be satisfactorily covered by the insulating layer, and the insulating layer can be satisfactorily embedded in the gaps between the thick conductor wirings. Therefore, productivity of a thick conductor wiring board in which defects such as electric shorts are suppressed can be improved. The printed wiring board of the present invention can be used in various applications such as a wiring board for wireless power supply.

### BRIEF DESCRIPTION OF DRAWINGS

FIG. 1 is a schematic cross-sectional view of a printed wiring board in which an insulating layer is provided.

### MODE FOR CARRYING OUT THE INVENTION

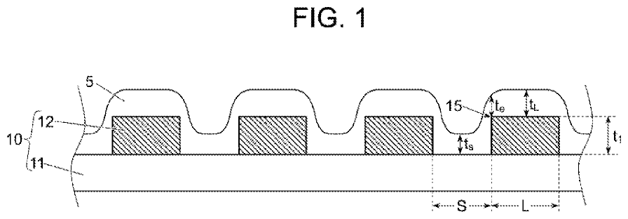

FIG. 1 is a schematic cross-sectional view illustrating an embodiment of a printed wiring board. An insulating resin layer 5 is provided on a wiring board 10 having conductor patterns 12 on an insulating substrate 11. Insulation between the wirings can be ensured by providing the insulating layer so as to fill spaces between adjacent wiring patterns. The printed wiring board may be a rigid wiring board using a rigid substrate, or a flexible wiring board using a flexible substrate, or a printed wiring board having both a flexible portion and a rigid portion. In the flexible printed wiring board, or in the flexible portion of the printed wiring board having the flexible portion and the rigid portion, wiring patterns formed of a conductor layer such as a copper layer are provided on a flexible insulating resin substrate such as a polyimide film. In a general printed wiring board, a conductor layer forming wiring patterns has a thickness of 10-35 μm, whereas the conductor patterns 12 in a thick conductor wiring board used in the present invention have a thickness of 50 μm or more.

For example, in a wiring board used for wireless power supply, it is necessary to lower electrical resistance of wirings in order to increase power transmission and reception efficiency. The wiring board 10 having the conductor patterns 12 that have a thickness of 50 μm or more is used. An upper limit of the thickness of the conductor patterns 12 is not particularly limited. However, from a point of view of increasing coverage by the insulating layer 5, the thickness of the conductor patterns 12 is preferably 150 μm or less, and more preferably 100 μm or less. In a flexible wiring board in which a flexible film such as a polyimide film is used as the insulating substrate 11, the flexibility can be maintained when the thickness of the conductor patterns is 100 μm or less. Also in a case where conductor patterns are formed in a flexible portion (on a flexible film) of an insulating substrate having a flexible portion and a rigid portion, in order to maintain the flexibility, the conductor patterns preferably have a thickness of 100 μm or less. The conductor patterns 12 particularly preferably have a thickness in a range of about 60-80 μm.

In the present invention, an insulating resin composition (solder resist ink) is applied by screen printing on the thick conductor wirings 12 of the thick conductor wiring board 10 and on the insulating substrate 11 between the thick conductor wirings and is subsequently cured, and thereby, a printed wiring board is obtained in which coverage of the conductors by the insulating layer and embeddability of the insulating layer between the conductors are ensured.

[Resin Composition]

The resin composition is not particularly limited as long as the resin composition has predetermined solution characteristics (solid content concentration, viscosity and thixotropic index) (to be described later) and is capable of forming an insulating layer on a wiring board by screen printing, and a resin composition of the same composition as that of a resist ink for a general printed wiring board can be used. From a point of view of increasing strength and solvent resistance of the insulating layer 5 on the wiring board 10, a thermosetting or photocurable resin composition is preferred. The resin composition may also be a photocurable and thermosetting composition having both a thermosetting component and a photocurable component. In general, the resin composition includes a binder polymer and a solvent.

<Binder Polymer>

The binder polymer is not particularly limited as long as the binder polymer is soluble with respect to the solvent. A weight molecular weight of the binder polymer is preferably 1,000-1,000,000. When the molecular weight of the binder polymer is in the above range, the binder polymer has excellent solubility with respect to the solvent, and the viscosity of the resin composition can be appropriately adjusted. A weight average molecular weight can be determined by polyethylene glycol conversion using gel permeation chromatography (GPC).

Examples of the binder polymer include a polyurethane-based resin, a poly (meth) acrylic resin, a polyvinyl-based resin, a polystyrene-based resin, a polyethylene-based resin, a polypropylene-based resin, a polyimide-based resin, a polyamide-based resin, a polyacetal-based resin, a polycarbonate-based resin, a polyester-based resin, a polyphenylene ether-based resin, a polyphenylene sulfide-based resin, a polyethersulfone-based resin, a polyetheretherketone-based resin, and the like.

The resin composition preferably contains a polyurethane-based resin as the binder polymer. The polyurethane-based resin is obtained by a reaction between a polyol compound and a polyisocyanate compound.

Examples of the polyol compound include polyoxyalkylene glycol, polyester diol, polycarbonate diol, polycaprolactone diol obtained by a ring-opening addition reaction of lactones, bisphenols, alkylene oxide adducts of bisphenols, hydrogenated bisphenols, alkylene oxide adducts of hydrogenated bisphenols, and the like. In particular, when a long chain diol such as polyalkylene glycol, polyoxyalkylene diol, polyester diol, polycarbonate diol, polycaprolactone diol or the like is used, an elastic modulus of an insulating layer obtained by curing the resin composition is decreased, and thus, there is a tendency that the flexibility is improved and the warpage is reduced. As the polyisocyanate compound, various aromatic polyisocyanate compounds and aliphatic polyisocyanate compounds can be used.

When the resin composition is photocurable, a polymer having a polymerizable group such as a (meth) acryloyl group and a soluble group such as a carboxyl group can be suitably used as the binder polymer.

<Solvent>

The solvent is not particularly limited as long as the solvent is capable of dissolving a resin component such as the binder polymer, and polar organic solvents such as sulfoxides, formamides, acetamides, pyrrolidones, acetates, ethers, hexamethylphosphoramide, and γ-butyrolactone can be suitably used. It is also possible to use these polar organic solvents and aromatic hydrocarbons such as xylene and toluene in combination. An amount of the solvent in the resin composition may be adjusted such that desired solution characteristics are obtained. In order to dissolve a resin component and obtain a solution suitable for screen printing, the amount of the solvent is preferably adjusted such that the solid content concentration of the resin composition is 40-70 wt %.

<Curable Resin Component>

A thermosetting or photocurable resin composition contains a curable resin component. A thermosetting resin composition preferably contains a thermosetting resin component in addition to the binder polymer and the solvent. The thermosetting resin component is a compound that generates a crosslinked structure and functions as a thermosetting agent. By generating a crosslinked structure, the thermosetting resin component can improve heat resistance, chemical resistance and electrical insulation reliability of the insulating layer. A photocurable resin composition contains a radical polymerizable compound or a photopolymerization initiator in addition to the binder polymer and the solvent. When necessary, the photocurable resin composition may further contain a thermosetting resin component or a carboxyl group-containing resin. A photocurable resin composition containing a carboxyl group-containing resin can be used as an alkali developing type resist suitable for fine pattern processing.

(Thermosetting Resin Component)

Examples of the thermosetting resin component include thermosetting resins such as an epoxy resin, a bismaleimide resin, a bisallylnadiimide resin, an acrylic resin, a methacrylic resin, a hydrosilyl hardening resin, an allyl cured resin, and a unsaturated polyester resin; a side chain reactive group type thermosetting polymer having a reactive group such as an allyl group, a vinyl group, an alkoxysilyl group, or a hydrosilyl group at a side chain or a terminal of a polymer chain; and the like.

By using an epoxy resin as the thermosetting resin component, heat resistance of an insulating layer obtained by curing, and adhesion of the insulating layer to conductors or an insulating substrate can be improved. The epoxy resin may be a monomer, an oligomer or a polymer as long as the epoxy resin has at least one epoxy group in a molecule. Among these epoxy resins, a polyfunctional epoxy resin containing two epoxy groups in a molecule is preferable. Examples of the polyfunctional epoxy resin include a bisphenol A type epoxy resin, a bisphenol F type epoxy resin, a bisphenol S type epoxy resin, a hydrogenated bisphenol A type epoxy resin, a biphenyl type epoxy resin, a phenoxy type epoxy resin, a naphthalene type epoxy resin, a phenol novolak type epoxy resin, a cresol novolak type epoxy resin, a trisphenol methane type epoxy resin, a dicyclopentadiene type epoxy resin, an amine type epoxy resin, a urethane-modified epoxy resin, a rubber-modified epoxy resin, a chelate-modified epoxy resin, and the like.

Examples of a curing agent of an epoxy resin include a phenol novolak resin, a cresol novolak resin, a phenol resin such as a naphthalene type phenol resin, an amino resin, a urea resin, melamine, dicyandiamide, and the like. Examples of a curing accelerator of an epoxy resin include phosphine-based compounds, amine-based compounds, borate-based compounds and the like, and imidazoles, imidazolines, azine-based imidazoles, and the like.

(Carboxyl Group-Containing Resin)

A carboxyl group-containing resin is a compound having at least one carboxyl group in a molecule. In a photocurable resin composition used as an alkali developing type resist, a carboxyl group-containing resin preferably contains at least one photopolymerizable functional group in a molecule. A weight average molecular weight of a carboxyl group-containing compound based on polyethylene glycol conversion is preferably 3,000-300,000. When the weight average molecular weight is in the above range, an excessive increase in the viscosity of the resin composition is suppressed, and further, there is a tendency that developability, flexibility and chemical resistance of the photocurable resin composition are improved.

An acid value of the carboxyl group-containing resin measured using a method specified in JIS K5601-2-1 is preferably 50-200 mgKOH/g, and more preferably 50-150 mgKOH/g. When the acid value of the carboxyl group-containing resin is in the above range, an insulating layer having low hygroscopicity, excellent electrical insulation reliability and excellent developability can be obtained.

Examples of the carboxyl group-containing resin include a carboxyl group-containing (meth) acrylic copolymer, a carboxyl group-containing vinyl-based copolymer, an acid-modified polyurethane, an acid-modified polyester, an acid-modified polycarbonate, an acid-modified polyamide, an acid-modified polyimide, and the like. Among these carboxyl group-containing resins, an acrylic copolymer containing (meth) acrylic acid and (meth) acrylic acid alkyl ester as copolymerization monomer components is excellent in photosensitivity, flexibility and chemical resistance and thus is preferable.

(Radical Polymerizable Compound)

A radical polymerizable compound is a compound that is polymerized by radicals generated by light or heat, and a compound having at least one unsaturated double bond in a molecule is preferable. As a functional group having an unsaturated double bond, an acrylic group, a methacryloyl group or a vinyl group is preferable.

As a radical polymerizable compound, an EO-modified di (meth) acrylate and a polyfunctional (meth) acrylic compound having 3 or more (meth) acryloyl groups in a molecule are preferable. The number of repeating EO (ethylene oxide) units contained in a molecule of di (meth) acrylate is preferably 2-50, and more preferably 2-40. By using these polyfunctional acrylates, solubility of the resin composition in a water-based developer such as an alkaline aqueous solution is improved, and a development time is shortened. Further, since a stress is unlikely to remain in an insulating layer obtained by curing the resin composition, when an insulating layer is formed in a flexible portion of a printed wiring board, a curl of the printed wiring board can be suppressed.

As the radical polymerizable compound, in addition to the above-described compounds, an epoxy-modified (meth) acrylic resin, a urethane-modified (meth) acrylic resin, a polyester-modified (meth) acrylic resin and the like may be used. By using two or more radical polymerizable compounds in combination, there is a tendency that heat resistance of the insulating layer after photocuring is improved.

(Polymerization Initiator)

A photopolymerizable resin composition preferably contains a photopolymerization initiator. A photopolymerization initiator is a compound that is activated by optical energy of UV or the like and initiates and promotes a photopolymerization reaction of the above-described radical polymerizable compound and the like, and various commonly known photoradical generators may be suitably selected and used. It is desirable to mix and use two or more photopolymerization initiators.

<Filler>

The resin composition preferably contains a filler. When the resin composition contains a filler, there is a tendency that the embeddability of the insulating layer between the wirings is improved and the warpage of the substrate due to a curing shrinkage is reduced. As the filler, an organic filler, an inorganic filler, an organic-inorganic composite filler and the like may be suitably select and used. Examples of materials of organic fillers include poly (meth) acrylic acid alkyl ester, crosslinked poly (meth) acrylic acid alkyl ester, crosslinked styrene, nylon, silicone, crosslinked silicone, crosslinked urethane, and the like. Examples of materials of inorganic fillers include: metal oxides such as silica, titanium oxide, and alumina; metal nitrides such as silicon nitride and boron nitride; metal salts such as calcium carbonate, calcium hydrogen phosphate, calcium phosphate, and aluminum phosphate; and the like. Examples of organic-inorganic composite fillers include a filler in which an inorganic material layer is formed on surfaces of organic fine particles, and a filler in which an organic material layer or organic fine particles are formed on surfaces of inorganic fine particles. It is also possible to use a filler surface-modified with a silane coupling agent or the like. From a point of view of improving insulation reliability between the wirings, an organic filler is preferable.

A shape of a filler may be spherical, powdery, fibrous, acicular, scaly or the like. Since a spherical filler has no anisotropy so that a stress is unlikely to be unevenly distributed, there is a tendency that occurrence of a strain is suppressed and the warpage of the substrate due to a curing shrinkage and the like is reduced. Therefore, a spherical filler is preferable. Among spherical fillers, from a point of view of improving the flexibility of the insulating layer after curing and suppressing the warpage of the substrate, a spherical organic filler is preferable, and crosslinked urethane beads containing a urethane bond in a molecule are particularly preferable. From a point of view of suppressing the warpage of the wiring board and maintaining insulation performance of the insulating layer between the wirings, a content of the filler in the resin composition with respect to 100 parts by weight of a total solid content is preferably 5-50 parts by weight, and more preferably 10-40 parts by weight.

The filler has an average particle size of, for example, about 0.01-20 μm. Since a filler having a large particle size causes insulation failure, it is preferable to use classified spherical organic beads. Specifically, it is preferable to use a spherical filler in which a number ratio of particles having a particle size of 15 μm or less is 99.99% or more. The particle size can be measured using a laser diffraction/scattering type particle size distribution measurement device, and a volume-based median diameter is taken as an average particle size.

<Other Components>

When necessary, the resin composition may contain various additives such as a photochromic agent, a thermal coloring preventing agent, a plasticizer, a dye, a pigment, a coloring agent, a defoaming agent, a flame retardant, a stabilizer, an adhesion imparting agent, a leveling agent, and an antioxidant.

Examples of flame retardants include a phosphoric acid ester compound, a halogen-containing compound, a metal hydroxide, an organic phosphorus compound, a silicone-based compound, and the like. Among these flame retardants, a phosphorus-based flame retardant is preferable.

[Method for Preparing Resin Composition]

The resin composition is prepared by mixing the above-described components. When necessary, the above-described components may be pulverized and dispersed. The pulverization and dispersion may be performed, for example, using a general kneading apparatus such as a bead mill, a ball mill, or a triple roll.

Examples of methods for adding a filler to the resin composition include: (1) a method in which a filler is directly mixed in the resin composition using a stirrer or the like; (2) a method in which a filler is added to a polymerization reaction solution before or during polymerization of a polymer in the resin composition; (3) a method in which a filler is mixed together with a polymer for the resin composition and other necessary components and the resulting mixture is kneaded or dispersed by a stress such as a shear stress of a triple roll, a bead mill, or the like; and the like. In order to satisfactorily disperse the filler and stabilize a dispersed state, a dispersing agent, a thickening agent and the like can also be used.

[Solution Characteristics of Resin Composition]

For the resin composition, a viscosity at 25° C. is preferably 50-300 poises, and a thixotropic index is preferably 1.1-3.5. When the resin composition has the above-described rheology and a predetermined screen printing plate is used, the coverage of the insulating layer on the thick conductor wirings and the embeddability of the insulating layer in gaps between the thick conductor wirings are improved. The viscosity of the resin composition is measured at a rotation speed of 50 rpm using a B type viscometer. The thixotropic index is a ratio of a measured value of the viscosity at a rotation speed of 5 rpm to a measured value of the viscosity at a rotation speed of 50 rpm.

When the viscosity of the resin composition is greater than 300 poises or when the thixotropic index is greater than 3.5, there is a tendency that the embeddability of the insulating layer into the gaps between the thick conductor wirings is reduced. On the other hand, when the viscosity of the resin composition is less than 50 poises or when the thixotropic index is less than 1.1, there is a tendency that the coverage of the insulating layer on the thick conductor wirings is reduced, and, in particular, a thickness of the insulating layer on edges of the conductor patterns is extremely small. The solution viscosity of the resin composition is more preferably 100-300 poises, even more preferably 130-270 poises, and particularly preferably 150-250 poises. The thixotropic index of the resin composition is more preferably 1.5-3.3, and even more preferably 2.0-3.2.

The viscosity and the thixotropic index of the resin composition can be controlled within the above ranges by controlling the molecular weight of the binder polymer, introducing a substituent group to the binder polymer, controlling the amount of the filler and the particle size of the filler, adding a resin component in a liquid form at a room temperature such as an reactive monomer, and the like. In order for the viscosity and the thixotropic index to be in the above ranges, the solid content concentration of the resin composition is preferably 40-70 wt %, more preferably 45-69 wt %, and even more preferably 50-68 wt %. The solid content concentration is a value measured according to JIS K 5601-1-2 under a drying condition of 170° C.×1 hour.

[Method for Forming Insulating Layer]

In formation regions (L) of the wirings 12 of the thick conductor wiring board 10 and on the insulating substrate 11 in regions (S) between the conductor patterns, the insulating layer is formed by printing the resin composition by screen printing, removing the solvent by drying, and curing the resin composition when necessary.

The screen printing method is a method in which printing is performed by scanning a printing squeegee on a screen printing plate carrying the resin composition and transferring the resin composition to a substrate to be printed. By applying an emulsion to the screen printing plate in a non-printing region, the resin composition can be only applied to a required region. Therefore, material usage efficiency is high. The screen printing method has an advantage that it is easy to form an insulating layer in a large area and a throughput with a simple process is also high and thus productivity is excellent.

It is also an advantage of the screen printing method that it is easy to print also on a substrate to be printed having irregularities such as a printed wiring board. When the resin composition is applied on a substrate to be printed, by scanning a rubber printing squeegee, it is possible to perform printing without being influenced by a surface shape of the base by utilizing a pressing force against the substrate to be printed.

In the present invention, a screen printing plate is used in which a mesh thickness (D) is 2.2 or more times a yarn diameter (d) of yarns. The mesh thickness is a thickness of a mesh woven with warp yarns and weft yarns that form a screen printing plate, and the yarn diameter is a diameter of the yarns that form the mesh. For meshes of the same woven structure, the mesh thickness (D) depends on the yarn diameter (d). The larger the yarn diameter is, the larger is the mesh thickness and the larger is a print film thickness. The mesh thickness (D) of a screen printing plate of a general woven structure is about 2 times the yarn diameter (d) of the yarns.

The larger the mesh thickness of the screen printing plate is, the larger is an amount of the resin composition filled in the printing plate, and thus the larger is the print film thickness. Even for a general screen printing plate in which the mesh thickness (D) is about 2 times the yarn diameter (d) of the yarns, when the yarn diameter (d) of the yarns is increased, the mesh thickness (D) increases. However, as the yarn diameter increases, a mesh aperture size decreases. Therefore, when a resin composition having a large viscosity or thixotropy is printed, since a leveling property is not sufficient, there is a tendency that the embeddability of the resin composition between the wirings is reduced.

In a screen printing plate in which the mesh thickness (D) is 2.2 or more times the yarn diameter (d) of the yarns, since the mesh thickness can be increased without decreasing the mesh aperture size, the print leveling property of the insulating layer is improved. Therefore, even when the viscosity or the thixotropy of the resin composition is large, the thick conductor wirings and spaces between the wirings can be more satisfactorily covered by the insulating layer.

In order to increase the coverage by the insulating layer, the mesh thickness (D) of the screen printing plate is preferably 0.8 or more times, more preferably 1.0 or more times, and even more preferably 1.5 or more times a thickness (t₁) of the conductor wirings. On the other hand, when the mesh thickness (D) is excessively large, there is a tendency that the warpage of the wiring board is increased due to a curing shrinkage of the insulating layer. Therefore, the mesh thickness (D) of the screen printing plate is preferably 3.5 or less times, more preferably 3 or less times, and even more preferably 2.8 or less times the thickness (t₁) of the conductor wirings. The mesh thickness (D) of the screen printing plate is preferably 40-200 μm, more preferably 70-190 μm, and even more preferably 80-180 μm. The mesh thickness (D) of the screen printing plate is more preferably 2.3-4.4 times, and even more preferably 2.5-3.5 times the yarn diameter (d). By adjusting the mesh thickness of the screen printing plate within the above range, the thickness of the insulating layer on the conductor patterns can be adjusted to 0.1-1 times the conductor thickness (t₁). The thickness of the insulating layer on the conductor patterns is preferably 0.3-0.7 times the conductor thickness (t₁).

A minimum unit of the woven structure of the screen printing plate is formed by knitting at least one warp yarn and at least one weft yarn, and mesh fabrics and the like of a plain weave, a twilled weave, a plain dutch weave and a twilled dutch weave can be suitably used. Among these, a structure (hereinafter referred to as “a thick woven structure”) in which warp yarns in a heavily wavy state are woven into substantially straight weft yarns is suitable as a screen printing plate in which the mesh thickness (D) is more than 2 times the yarn diameter (d) of the yarns. In the thick woven structure, the weft yarns stretched at a relatively high tension are substantially arranged on the same plane in a straight state without waving, and the warp yarns are in a heavily wavy state by being stretched at a relatively low tension and the mesh thickness is increased. As a screen mesh having such a thick woven structure, a thick woven structure stainless steel mesh (3D-mesh, 3D-165-126) manufactured by ASADA MESH Co., Ltd. or the like can be suitably used.

In a general screen printing plate in which the mesh thickness is about 2 times the yarn diameter, since the weft yarns are positioned alternately shifted from each other in an up-down direction (a normal direction of a printing surface), both the warp yarns and the weft yarns are in contact with a substrate to be printed during screen printing. On the other hand, in a screen printing plate of a thick woven structure, since the weft yarns are substantially positioned on the same plane and curvatures of the warp yarns are highly wavy up and down, the weft yarns do not come into contact with the substrate to be printed. The printing plate of the thick woven structure has a small contact area with the substrate to be printed, and the resin composition is filled up to the lower side (the contact surface with the substrate to be printed) of the screen printing plate. Therefore, there is a tendency that the print film thickness is further increased, and the printing plate is suitable for printing the resin composition to a thick conductor wiring board.

A material of the screen printing plate is not particularly limited. Synthetic fibers such as polyester and nylon, various metal materials such as stainless steel, nickel, nickel alloy, titanium, titanium alloy and copper can be used.

As a squeegee used for screen printing, a squeegee having a squeegee hardness of 55-85° can be particularly preferably used. When the squeegee hardness is smaller than 55°, there is a tendency that the pressing force against the substrate to be printed is small and the embeddability of the insulating layer into the gaps between the wirings is reduced. When the squeegee hardness is larger than 85°, the coverage of the insulating layer on the wirings may decrease.

An attack angle when the squeegee is in contact with the screen printing plate is preferably 60-90°. By adjusting the attack angle, a thickness (t_{L}) of the insulating layer on the thick conductor wirings and a thickness (tₛ) of the insulating layer between the wirings (between the conductor patterns) can be respectively controlled to 10-100% and 50-200% of the conductor thickness (t₁). When the attack angle is smaller than 60°, there is a tendency that the pressing force against the substrate to be printed is small and the embeddability of the insulating layer into the gaps between the wirings is reduced. When the attack angle is larger than 90°, a discharge amount of the resin composition may decrease, and the coverage of the insulating layer on the wirings may decrease.

The insulating layer 5 is formed by screen-printing the resin composition on the thick conductor wiring board 10 and then drying the coating film. A drying temperature is preferably 120° C. or lower, and more preferably 40-100° C. When the resin composition is thermosetting, thermal curing is performed after drying. An insulating layer having excellent heat resistance can be obtained by causing a thermally reactive functional group such as an epoxy group to react by a heat treatment. A curing temperature is preferably from 100-250° C., more preferably from 120-200° C., and even more preferably from 130-180° C. By setting a final heating temperature to 250° C. or lower, deterioration due to oxidation of the wirings can be suppressed.

For the insulating layer 5 after thermal curing, the thickness (t_{L}) on the wirings is preferably 0.1 or more times the conductor thickness (t₁), and the thickness (t_{S}) between the wirings is preferably 0.5 or more times the conductor thickness (t₁). When the thicknesses of the insulating layer are within the above ranges, electrical insulation between the wirings is improved. For the insulating layer 5 after thermal curing, the thickness (t_{L}) on the wirings is preferably 1 or less times the conductor thickness (t₁), and the thickness (t_{S}) between the wirings is preferably 2 or less times the conductor thickness (t₁). When the thicknesses of the insulating layer are within the above ranges, warpage of the wiring board due to a curing shrinkage of the insulating layer can be suppressed.

According to the present invention, a printed wiring board can be provided in which the thickness (t_{S}) of the insulating layer between the conductor patterns of the wiring board is 0.5-2 times the conductor thickness (t₁). The thickness (t_{S}) of the insulating layer between the conductor patterns of the wiring board is preferably 0.7-1.7 times the conductor thickness (t₁), and more preferably 0.9-1.5 times the conductor thickness (t₁).

According to the present invention, on the printed wiring board having the conductor patterns that have a thickness of 50 μm or more, the insulating layer (solder resist) of which the thickness (t_{L}) on the conductor patterns is 0.1-1 times the conductor thickness (t₁) can be formed by performing screen printing once. The thickness (t_{L}) of the insulating layer on the conductor patterns is preferably 0.3-0.7 times the conductor thickness (t₁). In order to improve the coverage of the conductor patterns 12 with the insulating layer 5, a thickness (tₑ) of the insulating layer 5 on edges 15 of the conductor patterns is preferably 0.1-1 times, and more preferably 0.3-0.7 times the conductor thickness (t₁). The thickness (tₑ) of the insulating layer 5 on the edges 15 is preferably 0.3 or more times the thickness (t_{L}) of the insulating layer at centers of the conductor patterns. As described above, by using the resin composition having a predetermined thixotropy and the screen printing plate having a predetermined mesh thickness, an insulating layer having a predetermined thickness and excellent coverage can be formed on the thick conductor wiring board.

### EXAMPLES

In the following, the present invention is described in detail based on examples. However, the present invention is not limited by these examples.

### Synthesis Example 1: Preparation of Urethane Polymer Solution

30.00 g of methyltriglyme (1,2-bis (2-methoxyethoxy) ethane) as a polymerization solvent, and 10.31 g (0.050 mol) of norbornene diisocyanate were charged into a reaction container equipped with a stirrer, a thermometer and a nitrogen inlet tube, and were dissolved by heating the mixture to 80° C. while the mixture was stirred under a nitrogen stream. To this solution, a solution, which was obtained by dissolving 50.00 g (0.025 mol) of polycarbonate diol (manufactured by Asahi Kasei Corporation under a product name PCDL T5652 having a weight average molecular weight of 2000) and 3.70 g (0.025 mol) of 2,2-bis (hydroxymethyl) butanoic acid in 30.00 g of methyltriglyme, was added over 1 hour. Thereafter, the mixture was heated and stirred at 80° C. for 5 hours to allow the components to react with each other, and a carboxyl group-containing urethane polymer solution was obtained. A solid content concentration of the solution was 52 wt %, a weight average molecular weight of a polymer was 5,600, and an acid value was 22 mgKOH/g.

Blending Examples 1-12: Preparation of Resin Composition

A binder polymer, an epoxy resin, a curing accelerator, radical polymerizable polyfunctional acrylate, a filler, a solvent and other components (a photopolymerization initiator, a flame retardant, a coloring agent, and a defoaming agent) were blended in the compositions of Blending Examples 1-12 shown in Table 1. After the components were mixed using a general stirring device equipped with a stirring blade, the mixture was passed twice through a triple roll mill to obtain a uniform solution. In Blending Examples 1-12, compositions of the binder polymer (a total of 82 parts by weight), the curing agent (1 part by weight), the polyfunctional acrylate (a total of 15 parts by weight), the photopolymerization initiator (a total of 3.3 parts by weight), the coloring agent (a total of 1.2 parts by weight) and the defoaming agent (2.5 parts by weight) were not changed, and types and contents of the epoxy resin, the flame retardant, the filler and the solvent were changed to adjust the solution characteristics (the solid content concentration and the viscosity). In Blending Example 11, since the solid content concentration was large, preparation of the resin composition was difficult. In Blending Example 12, since the solid content concentration was small, after the resin composition was prepared, separation of a solid content was observed. Particle sizes of the resin compositions of Blending Examples 1-10 were measured using a grind meter, and the particles sizes were all 10 μm or less. After the solution was defoamed using a defoaming device, the following evaluations were performed.

(Viscosity and Thixotropic Index)

The viscosity of each of the resin compositions of Blending Examples 1-10 was measured in an environment of 25° C. using a B type viscometer (manufactured by Brookfield Co., Ltd., rotor No. 4) at rotation speeds of 5 rpm and 50 rpm, and the thixotropic index was calculated from a ratio of the viscosity measured at 5 rpm to the viscosity measured at 50 rpm.

(Solid Content Concentration)

Measurement was performed according to HS K 5601-1-2. A drying condition was set to 170° C.×1 hour. In Blending Example 11, since the resin composition could not be prepared, a solid content concentration calculated from the blending amounts is shown in Table 1.

The compositions and the solution characteristics (the solid content concentration, the viscosity (the value measured at 50 rpm) and the thixotropic index) of Blending Examples 1-12 are shown in Table 1. The methyltriglyme in Table 1 is a total amount including also the solvent contained in the polymer solution of Synthesis Example 1.

TABLE 1

| | Blending Example | | 1 | 2 | 3 | 4 | 5 | 6 | 7 | 8 | 9 | 10 | 11 | 12 |
|---|---|---|---|---|---|---|---|---|---|---|---|---|---|---|
| Solution | Solid Content Concentration (%) | | 66.8 | 67.7 | 64.0 | 64.0 | 55.8 | 55.8 | 57.1 | 67.9 | 63.8 | 61.0 | 70.2 | 39.9 |
| Character- | Viscosity (poise) | | 206 | 293 | 53 | 53 | 102 | 153 | 172 | 322 | 48 | 116 | | |
| istics | Thixotropic Index | | 3.0 | 3.0 | 3.3 | 3.5 | 1.1 | 1.6 | 2.0 | 2.9 | 3.3 | 3.6 | | |
| Compo- | Binder | Polymer of Synthesis Example 1 | 25 | | | | | | | | | | | |
| sition | Polymer | UXE-3044 <1> | 27 | | | | | | | | | | | |
| | | ZAR-2000 <2> | 27 | | | | | | | | | | | |
| | | EBECRYL 8413 <3> | 3 | | | | | | | | | | | |
| | Epoxy Resin | jER 828US <4> | 13 | 13 | 13 | 13 | 13 | 0 | 0 | 13 | 13 | 13 | 13 | 13 |
| | | YX-4000K <5> | 10 | 10 | 10 | 10 | 10 | 23 | 30 | 10 | 10 | 10 | 10 | 10 |
| | Curing Accelerator | DICY-7 <6> | 1 | | | | | | | | | | | |
| | Polyfunctional | Kayarad DPHA <7> | 10 | | | | | | | | | | | |
| | Acrylate | FA-321M <8> | 5 | | | | | | | | | | | |
| | Photopoly- | IRGACURE 369E <9> | 3 | | | | | | | | | | | |
| | merization | Irgacure OXE-02 <10> | 1 | | | | | | | | | | | |
| | Initiator | KAYACURE DETX-S <11> | 0.3 | | | | | | | | | | | |
| | Flame Retardant | Exolit OP 935 <12> | 47 | 47 | 47 | 47 | 0 | 0 | 0 | 47 | 47 | 47 | 47 | 47 |
| | Filler | Art Pearl TK-900TR <13> | 31 | 31 | 31 | 0 | 0 | 0 | 0 | 31 | 31 | 31 | 31 | 31 |
| | | Art Pearl TK-1000TR <14> | 0 | 0 | 0 | 31 | 0 | 0 | 0 | 0 | 0 | 0 | 0 | 0 |
| | Coloring Agent | Heliogen Blue D 7110 F <15> | 0.5 | | | | | | | | | | | |
| | | Graphtol Yellow H2R <16> | 0.7 | | | | | | | | | | | |
| | Defoaming Agent | Floren AC-2000 <17> | 2.5 | | | | | | | | | | | |
| | Solvent | Ethyl Diglycol Acetate | 86 | 82 | 100 | 100 | 86 | 86 | 86 | 81 | 101 | 116 | 71 | 296 |
| | | Methyltriglyme | 17 | 17 | 17 | 17 | 17 | 17 | 17 | 17 | 17 | 17 | 17 | 17 |

Details of the components <1>-<17> in Table 1 are as follows.

<1> Carboxyl group-containing urethane-modified epoxy (meth) acrylate resin manufactured by Nippon Kayaku Co., Ltd. under a product name of “KAYARAD UXE-3044.”

<2> Carboxyl group-containing acid-modified epoxy (meth) acrylate resin manufactured by Nippon Kayaku Co., Ltd. under a product name of “KAYARAD ZAR-2000.”

<3> Urethane acrylate manufactured by Daicel-Ornecs Co., Ltd. under a product name of “EBECRYL 8413.”

<4> Liquid epoxy resin manufactured by Mitsubishi Chemical Corporation under a product name of “jER 828US.”

<5> Powdered biphenyl type epoxy resin manufactured by Mitsubishi Chemical Corporation under a product name of “jER YX4000K.”

<6> Dicyandiamide manufactured by Mitsubishi Chemical Corporation under a product name of “jER Cure DICY 7.”

<7> Ultraviolet curable resin manufactured by Nippon Kayaku Co., Ltd. under a product name of “Kayarad DPHA.”

<8> EO-modified bisphenol A dimethacrylate manufactured by Hitachi Chemical Co., Ltd. under a product name of “FA-321M.”

<9> Alkylphenone-based photopolymerization initiator manufactured by BASF Japan Ltd. under a product name of “IRGACURE 369E.”

<10> Oxime ester-based photopolymerization initiator manufactured by BASF Japan Ltd. under a product name of “Irgacure OXE-02.”

<11> Thioxanthone-based photopolymerization initiator manufactured by Nippon Kayaku Co., Ltd. under a product name of “KAYACURE DETX-S.”

<12> A flame retardant manufactured by Clariant Japan Co., Ltd. under a product name of “Exolit OP-935” having a weight decrease starting temperature TGA of 353° C.

<13> Polycarbonate-based crosslinked urethane beads manufactured by Negami Kogyo Co., Ltd. under a product name of “Art Pearl TK-900TR.”

<14> Polycarbonate-based crosslinked urethane beads manufactured by Negami Kogyo Co., Ltd. under a product name of “Art Pearl TK-1000TR.”

<15> Copper phthalocyanine-based organic pigment manufactured by BASF Japan Ltd. under a product name of “Heliogen Blue D 7110F.”

<16> Yellow coloring agent manufactured by Clariant Japan Co., Ltd. under a product name of “Graphtol Yellow H2R.”

<17> Butadiene-based defoaming agent manufactured by Kyoeisha Chemical Co., Ltd. under a product name of “Floren AC-2000.”

<Formation of Insulating Layer on Thick Conductor Wiring Board>

Using a screen printing machine (manufactured by Mino Group Co., Ltd. under a product name of “Minomat 5575”), the above resin composition was screen-printed on a thick conductor wiring board using a rubber squeegee (manufactured by Mino Group Co., Ltd.) with a squeegee hardness of 75° at an attack angle of 75°, and was dried at 80° C. for 20 minutes and then was gradually cooled to a room temperature. Thereafter, the resin composition was heated and cured at 150° C. for 30 minutes, and an insulating layer was formed on the thick conductor wiring board. As the thick conductor wiring board, a flexible wiring board (manufactured by Taiyo Kogyo Co., Ltd.) having 70 mm×50 mm circuit-like rolled copper wirings (having a thickness of 70 μm) on a polyimide film having a thickness of 25 μm was used.

In Production Examples 1-5, the following stainless steel mesh screen printing plates were respectively used. In Production Example 3, the insulating layer was formed using all of the resin compositions of Blending Examples 1-10. For the others, the insulating layer was formed using the resin compositions of Blending Examples 1-5 and Blending Examples 8-10.

Production Example 1: manufactured by Asada Mesh Co., Ltd. under a product name of “BS-200/40” having a yarn diameter of 40 μm and a mesh thickness of 82 μm (D=2.1 d)

Production Example 2: manufactured by Asada Mesh Co., Ltd. under a product name of “BS-250/35” having a yarn diameter of 35 μm and a mesh thickness of 78 μm (D=2.2 d)

Production Example 3: manufactured by Asada Mesh Co., Ltd. under a product name of “3D-165-126” having a yarn diameter of 45 μm and a mesh thickness of 126 μm (D=2.8 d)

Production Example 4: manufactured by Mesh Co., Ltd. under a product name of “Solid” having a yarn diameter of 62 μm and a mesh thickness of 174 μm (D=4.4 d)

Production Example 5: manufactured by Mesh Co., Ltd. under a product name of “Solid” having a yarn diameter of 43 μm and a mesh thickness of 190 μm (D=4.7 d)

<Evaluation of Coverage>

By cross-section microscopic observation of a test piece obtained above, thicknesses of the insulating layer on the thick conductor wirings and on the polyimide substrate between the wirings (between the conductor patterns) were measured, and were evaluated according to the following criteria.

(Coverage on Wirings)

A: The insulating layer thickness is 21 μm or more (30% or more of the conductor thickness).

B: The insulating layer thickness is 7 μm or more and less than 21 μm (10% or more and less than 30% of the conductor thickness).

C: The insulating layer thickness is less than 7 μm (less than 10% of the conductor thickness).

(Coverage Between Wirings)

A: The insulating layer thickness is 49 μm or more (70% or more of the conductor thickness).

B: The insulating layer thickness is 35 μm or more and less than 49 μm (50% or more and less than 70% of the conductor thickness).

C: The insulating layer thickness is less than 35 μm (less than 50% of the conductor thickness).

<Evaluation of Warpage>

A test piece was cut into an area of 75 mm×55 mm around the wirings and was placed on a smooth table such that the insulating layer was on an upper surface side, and a distance between the table and an edge portion of the test piece was measured.

The coverage and warpage evaluation results for the insulating layers of the printed wiring boards obtained in Production Examples 1-5 are shown in Table 2.

TABLE 2

| | Screen | | | | | | | | | | | |
|---|---|---|---|---|---|---|---|---|---|---|---|---|
| | Plate Mech | | | | | | | | | | | |
| | Thickness | Blending | 1 | 2 | 3 | 4 | 5 | 6 | 7 | 8 | 9 | 10 |
| Production | 2.1 d | Coverage on | C | A | C | C | C | — | — | C | C | C |
| Example 1 | | Wirings | | | | | | | | | | |
| | | Coverage | C | C | A | C | A | | | C | C | C |
| | | between Wirings | | | | | | | | | | |
| | | Warpage | 0.0 | 0.0 | 0.0 | 0.0 | 3.0 | | | 0.0 | 0.0 | 0.0 |
| | | (mm) | | | | | | | | | | |
| Production | 2.2 d | Coverage on | A | A | B | B | B | — | — | C | C | C |
| Example 2 | | Wirings | | | | | | | | | | |
| | | Coverage | A | B | A | A | A | | | C | C | C |
| | | between Wirings | | | | | | | | | | |
| | | Warpage | 0.0 | 0.8 | 0.0 | 0.0 | 4.0 | | | 1.3 | 0.0 | 0.0 |
| | | (mm) | | | | | | | | | | |
| Production | 2.8 d | Coverage on | A | A | A | A | A | A | A | C | C | C |
| Example 3 | | Wirings | | | | | | | | | | |
| | | Coverage | A | A | A | A | A | A | A | C | C | C |
| | | between Wirings | | | | | | | | | | |
| | | Warpage | 1.3 | 2.0 | 1.0 | 2.0 | 4.5 | 6.0 | 6.8 | 2.5 | 0.6 | 0.0 |
| | | (mm) | | | | | | | | | | |
| Production | 4.4 d | Coverage on | A | A | A | A | A | — | — | B | C | C |
| Example 4 | | Wirings | | | | | | | | | | |
| | | Coverage | A | A | A | A | A | | | C | B | B |
| | | between Wirings | | | | | | | | | | |
| | | Warpage | 3.0 | 3.3 | 2.8 | 3.5 | 4.8 | | | 3.8 | 2.0 | 0.8 |
| | | (mm) | | | | | | | | | | |
| Production | 4.7 d | Coverage on | A | A | A | A | A | — | — | B | C | C |
| Example 5 | | Wirings | | | | | | | | | | |
| | | Coverage | A | A | A | A | A | | | B | B | B |
| | | between Wirings | | | | | | | | | | |
| | | Warpage | 5.2 | 6.0 | 5.0 | 5.2 | 6.0 | | | 6.5 | 3.5 | 2.0 |
| | | (mm) | | | | | | | | | | |

### Reference Examples: Evaluation of Influence of Squeegee Hardness and Attack Angle

Insulating layers were formed using the resin composition of Blending Example 1 and the same screen printing plate as Production Example 3 and changing the hardness of the squeegee for screen printing in a range of 55-75° (Reference Example 1) and the attack angle in a range of 60-90° (Reference Examples 4-6), and the same evaluations as the above were performed. In all of the reference examples, the warpage was within 3 mm. The evaluation results of the insulating layer coverage are shown in Table 3.

TABLE 3

| | Squeegee | Attack | Insulating Layer Coverage | |
|---|---|---|---|---|
| | Hardness | Angle | On Wirings | Between Wirings |
| Reference Example 1 | 55° | 75° | A | B |
| Reference Example 2 | 80° | 75° | A | A |
| Reference Example 3 | 85° | 75° | B | A |
| Reference Example 4 | 75° | 60° | A | B |
| Reference Example 5 | 75° | 80° | A | A |
| Reference Example 6 | 75° | 90° | B | A |

From Production Example 3 of Table 2 and the results shown in Table 3, it is clear that the coverage between the wirings tends to decrease when the squeegee hardness is small and when the attack angle is small, and the coverage on the wirings tends to decrease when the squeegee hardness is large and when the attack angle is large. From these results, it is clear that, in screen printing of the resin composition onto the thick conductor wiring board, there are range of the squeegee hardness and the attack angle suitable for both the coverage on the wirings and the coverage between the wirings.

From the results shown in Table 2, it is clear that the resin composition of Blending Example 8 having a large viscosity, the resin composition of Blending Example 9 having a small viscosity, and the resin composition of Blending Example 10 having a large thixotropic index are poor in printability by screen printing, and the wirings and the regions between the wirings cannot be sufficiently covered by the insulating layer using any of the screen printing plates. For the resin compositions of Blending Examples 1-5, in Production Example 1 using the screen printing plate in which the mesh thickness is 2.1 times the yarn diameter, the coverage on the wirings and/or the coverage between the wirings were not sufficient. However, in Production Examples 2-5 using the screen printing plates in which the mesh thickness is 2.2 or more times the yarn diameter, the coverage on the wirings and the coverage between the wirings by the insulating layer were improved.

From the results of Production Example 1 and Production Example 2 using the resin compositions of Blending Examples 1-5, it is clear that, when the viscosity of the resin composition is small and when the thixotropic index is small (Blending Examples 3, 4, 5), the coverage on the wirings tends to decrease. This is thought to be due to that the solution has a high flowability and thus the resin composition printed on the wirings can easily flow into regions between the wirings. On the other hand, it is clear that, when the viscosity of the resin composition is large (Blending Example 2), the coverage between the wirings tends to decrease. This is thought to be due to that the solution has a low flowability and thus it is hard for the resin composition to enter into regions between the wirings.

For the resin compositions of Blending Examples 1-5, as the mesh thickness increases, the warpage of the substrate tends to increase. In Production Example 5 using the screen printing plate having a mesh thickness of 190 μm, in all of Blending Examples 1-5, the warpage exceeded 5 mm. From these results, it is clear that, by printing a resin composition having predetermined rheological properties using a screen printing plate in which a mesh thickness is about 3 times a yarn diameter of yarns, both thick conductor wirings and regions between the wirings can be satisfactorily covered by an insulating layer and warpage of a flexible substrate can be suppressed.

When the resin composition of Blending Example 5 that does not contain a filler was used, in all of Production Examples 1-5, the warpage was larger as compared to Blending Examples 1-4. In Blending Example 6 and Blending Example 7, in which the viscosity and the thixotropic index were increased as compared to Blending Example 5 by not containing a filler and changing the composition of the epoxy resin, the warpage of the substrate was further increased as compared to Blending Example 5. It is thought that, by containing a filler in the resin composition, a stress during thermal curing is relaxed and the warpage of the substrate is reduced. From the above results, it is clear that, by printing a resin composition containing a filler and having a predetermined rheology using a screen printing plate having a predetermined mesh thickness, a thick conductor wiring board having an insulating layer, in which both thick conductor wirings and regions between the wirings are satisfactorily covered by the insulating layer and warpage is small, can be obtained.

1. A method for manufacturing a printed wiring board having an insulating substrate, conductor patterns provided on the insulating substrate, and an insulating layer provided on the conductor patterns and the insulating substrate between the conductor patterns, the method comprising:
printing a resin composition by screen printing on the conductor patterns and on the insulating substrate between the conductor patterns, and then curing the resin composition such that the insulating layer is formed,
wherein the conductor patterns have a thickness of 50 μm or more,
the resin composition has a viscosity of 50-300 P at 25° C. and a thixotropic index of 1.1-3.5,
the screen printing is conducted by using a screen printing plate having a mesh thickness of 2.2 or more times a yarn diameter of yarns, and
a thickness of the insulating layer on the conductor patterns is 0.1-1 times a thickness of the conductor patterns.

2. The method according to claim 1, wherein a thickness of the insulating layer on the insulating substrate between the conductor patterns is 0.5-2 times the thickness of the conductor patterns.

3. The method according to claim 1, wherein the mesh thickness of the screen printing plate is 4.4 or less times the yarn diameter of the yarns.

4. The method according to claim 1, wherein the mesh thickness of the screen printing plate is 40-200 μm.

5. The method according to claim 1, wherein the thickness of the conductor patterns is 100 μm or less.

6. The method according to claim 1, wherein the resin composition comprises a binder polymer, a solvent, and a filler.

7. The method according to claim 6, wherein the filler is a spherical organic filler.

8. The method according to claim 6, wherein the resin composition comprises a urethane-based polymer as the binder polymer.

9. The method according to claim 6, wherein the resin composition further comprises an epoxy resin.

10. The method according to claim 6, wherein the resin composition further comprises a compound having a carboxy group and a polymerizable group in a molecule.

11. The method according to claim 6, wherein the resin composition further comprises a photopolymerization initiator.

12. The method according to claim 1, wherein a solid content concentration of the resin composition is 40-70 wt %.

13. The method according to claim 1, wherein the conductor patterns are provided in a flexible portion of the insulating substrate.

14. A printed wiring board, comprising:
an insulating substrate;
conductor patterns having a thickness of 50 μm or more provided on the insulating substrate; and
an insulating layer provided on the conductor patterns and on the insulating substrate between the conductor patterns,
wherein a thickness of the insulating layer on the conductor patterns is 0.1-1 times a thickness of the conductor patterns at both centers and edges of the conductor patterns.

15. The printed wiring board according to claim 14, wherein
the thickness of the insulating layer on the conductor patterns is 0.3-0.7 times the thickness of the conductor patterns at both centers and edges of the conductor patterns.

16. The printed wiring board according to claim 14, wherein a thickness of the insulating layer at edges of the conductor patterns is 0.3 or more times a thickness of the insulating layer at centers of the conductor patterns.

17. The method according to claim 1, wherein the thickness of the insulating layer on the conductor patterns is 0.1-1 times the thickness of the conductor patterns at both centers and edges of the conductor patterns.

18. The method according to claim 1, wherein the thickness of the insulating layer on the conductor patterns is 0.3-0.7 times the thickness of the conductor patterns at both centers and edges of the conductor patterns.

19. The method according to claim 1, wherein a thickness of the insulating layer at edges of the conductor patterns is 0.3 or more times a thickness of the insulating layer at centers of the conductor patterns.
